(19) United States
(12) Patent Application Publication
(10) Pub. No.: US 2009/0121313 A1
(43) Pub. Date: May 14, 2009

(54) SEMICONDUCTOR DEVICE WITH AT LEAST ONE AIR GAP PROVIDED IN CHIP OUTER AREA

(75) Inventor: Keiji HASHIMOTO, Tokyo (JP)

Correspondence Address: MCDERMOTT WILL & EMERY LLP, 600 13TH STREET, N.W., WASHINGTON, DC, 20005-3096, US

(73) Assignee: RENESAS TECHNOLOGY CORP.

(21) Appl. No.: 12/263,859

(22) Filed: Nov. 3, 2008

(30) Foreign Application Priority Data
Nov. 12, 2007 (JP) JP2007-292958

(51) Int. Cl. H01L 29/00; H01L 21/00; H01L 21/44

(52) U.S. Cl. 257/522; 438/463; 438/667; 257/E29.001; 257/E21.001; 257/E21.476

(57) ABSTRACT

One air gap structure is disposed so as to circle around the outer wall of a seal ring in a loop by arranging, within first insulating films located in a chip outer area corresponding to an outer area of the seal ring, air gaps into a line in parallel to the seal ring, which air gaps are hermetically-closed holes that are provided respectively in wiring layers other than portions corresponding to a global wiring layer and are extended in the thickness direction of first insulating films. When a crack occurs at a chip peripheral edge due to dicing or the like, the advancing direction thereof is changed by the air gaps to an upward direction, thereafter the crack advances toward the uppermost position in the chip outer area along the extending direction of the one air gap structure, so that the crack cannot reach the seal ring.

### BACKGROUND OF THE INVENTION

1. Field of the Invention

The present invention relates to structures of semiconductor devices and methods of manufacturing the same.

2. Description of the Background Art

Higher integration and higher speeds are pursued with semiconductor devices, furthering miniaturization thereof. In the wiring process as part of the semiconductor process also, wiring has become increasingly fine. Conventionally, furtherance of miniaturization propelled attainment of higher speeds at the same time. In today's semiconductor technique, however, delay due to wiring, which did not matter in the conventional technique, has increased its significance with the advancement of miniaturization and has become a nonnegligible problem. The delay due to wiring is proportional to the product of the wiring resistance R and the capacitance C and is referred to as RC delay. In order to reduce the wiring resistance R, conceivable is introduction of Cu, which has low resistivity, into wiring materials, and Cu has begun to be used as a wiring material gradually as from the 130 nm-node generation. On the other hand, to deal with the capacitance C, a low-permittivity film (a so-called low-k film) has been introduced as a material for wiring interlayer dielectrics. In the 90 nm node, a material with k≈3 is used as a material for wiring interlayer dielectrics. In the 65 nm node or 45 nm node, a ultra low-k film with k≈2.7 (hereinafter referred to as a ULK film) is used, and in a coming generation, an extra low-k film with a further lower permittivity (hereinafter referred to as an ELK film) is going to be used.

Low-permittivity films, however, are inferior to TEOS oxide films or FSG films that were used as interlayer dielectrics in the past, in respect to mechanical strength. It has turned out that, in a case where such a low-permittivity film is used as an interlayer dielectric, the interlayer dielectric is prone to peel off at an end of a semiconductor chip in an assembly process such as dicing or packaging. Accordingly, for using such a low-permittivity film as an interlayer dielectric, various attempts are being made, such as developing a suitable packaging resin or designing a better layout.

Seeking of low permittivity materials for interlayer dielectrics leads to a structure in which an area corresponding to an interlayer dielectric is in a vacuum state or is sealed with a gas, which is the lowest in permittivity. Such a structure is referred to as an air gap structure, air-bridge structure, air-wiring structure, and so forth. In the following description, this structure, i.e., a space or a hole that is provided in an interlayer dielectric and is hermetically closed, is referred to as an “air gap”, including embodiments described in the present invention.

Nevertheless, even when an air gap structure is used in an effective element area (circuit wiring area), if an insulating film in a portion around the air gap structure that is left unremoved has high permittivity, wiring delay is caused in that portion. For this reason, it is preferable to use a low-permittivity film for an interlayer dielectric to be unremoved. In this case, too, it is necessary to take measures to compensate for the lack of mechanical strength of the semiconductor device.

Japanese Patent Application Laid-Open No. 2007-19080 discloses a technique of causing a low-k film on an end surface of a semiconductor chip to recede inward so that a molding resin and the low-k film do not contact each other, in order to protect from a crack caused by the action on the low-k film of the stress produced in the molding resin in packaging. Japanese Patent Application Laid-Open No. 2007-115988 discloses a technique of providing a slit between a portion to be diced and a seal ring to render the slit act as a stress reliever layer, in order to protect from a crack caused by the action on a low-k film of the stress produced in a molding resin in packaging. Japanese Patent Application Laid-Open No. 2007-201182 discloses a technique of removing an impurity layer between a portion to be diced and a seal ring portion to eliminate a cause for a crack, because impurities are doped in a substrate on which the seal ring is provided, and the impurity layer is so low in strength as to be a base point of a crack in dicing at an end of a chip. These known techniques describe embodiments in which closed cavities are provided within laminated interlayer films between the seal ring and the area to be diced; however, these known techniques do not include an idea that such a cavity is provided between dummy metal portions.

In a conventional semiconductor device, as illustrated in the longitudinal cross-sectional view of FIG. 17, a crack 12 occurs from a dicing line in dicing or during a packaging process, and the crack 12 reaches a seal ring 30 to cause damage on the seal ring 30. Owing to this, moisture enters from the damaged portion to reach an effective element area 1 inside a chip, which induces faulty operation and degradation in reliability. As shown in FIG. 17, while the crack 12 also occurs at an interface between ELK or ULK interlayer films 6, the crack 12 occurs particularly along an interface between an etching stopper film (e.g., SiC, SiCN, SiCO, SiN, or a laminated film thereof) that locates between an interlayer film 6 and a contact interlayer film 5, and the interlayer film; that is, the crack 12 occurs at the interface between an etching stopper film which is a hard film as described above and an ELK film or a ULK film which is a soft film.

### SUMMARY OF THE INVENTION

The present invention was made to overcome the foregoing problems, and it is an object of the present invention to provide a semiconductor device with a structure in which a crack does not reach a seal ring, or a crack itself does not occur, even after a dicing process and a packaging process.

According to the subject matter of the present invention, in an outer area of a seal ring area including a seal ring, within first insulating films that have a lower permittivity than a contact interlayer dielectric, a plurality of air gaps, each being extended parallel to the thickness direction of each first insulating film, are arranged in a line along the thickness direction of the first insulating films so as to encircle the seal ring.

These and other objects, features, aspects and advantages of the present invention will become more apparent from the following detailed description of the present invention when taken in conjunction with the accompanying drawings.

According to the subject matter of the present invention, even if a crack occurs at an end of a semiconductor chip during a dicing process or a packaging process, the air gaps change the advancing direction of the crack to the thickness direction of the first insulating films, with the result that the crack can be prevented from reaching the seal ring. Accordingly, it is possible to remarkably suppress the occurrence of defects such as lowering of reliability of the semiconductor device due to the dicing process or packaging process.

### BRIEF DESCRIPTION OF THE DRAWINGS

FIG. 1 is a plan view schematically showing the structure of a semiconductor chip included in a semiconductor device according to a first embodiment of the present invention;

FIG. 2 is a plan view schematically showing a modification of the structure of the semiconductor chip included in the semiconductor device according to the first embodiment of the present invention;

FIG. 3 is a longitudinal cross-sectional view showing the structure of the semiconductor chip included in the semiconductor device according to the first embodiment of the present invention;

FIG. 4 is a longitudinal cross-sectional view showing an effect exhibited by the semiconductor device according to the first embodiment of the present invention;

FIGS. 5A to 5D and 6E and 6F are longitudinal cross-sectional views showing a method of manufacturing the semiconductor chip included in the semiconductor device according to a second embodiment of the present invention;

FIG. 7 is a longitudinal cross-sectional view showing the structure and an effect of a semiconductor chip included in a semiconductor device according to a third embodiment of the present invention;

FIG. 8 is a plan view schematically showing the structure of a semiconductor chip included in a semiconductor device according to a fourth embodiment of the present invention;

FIG. 9 is a plan view schematically showing, in an enlarged manner, the structure at a corner portion of the semiconductor chip included in the semiconductor device according to the fourth embodiment of the present invention;

FIG. 10 is a longitudinal cross-sectional view taken along line B1-B2 of FIG. 9;

FIG. 11 is a longitudinal cross-sectional view showing the structure of a semiconductor chip included in a semiconductor device according to a fifth embodiment of the present invention;

FIG. 12 is a plan view schematically showing an effect provided by the semiconductor chip according to the fifth embodiment of the present invention;

FIG. 13 is a longitudinal cross-sectional view schematically showing the structure of an area to be irradiated with a laser beam of a semiconductor wafer for use in a semiconductor manufacturing method according to a sixth embodiment of the present invention;

FIG. 14 is a longitudinal cross-sectional view showing a process of melting an Si substrate by applying a laser beam onto the area to be irradiated with a laser beam of the semiconductor wafer;

FIG. 15 is a longitudinal cross-sectional view schematically illustrating a problem in a process of separating a semiconductor chip;

FIG. 16 is a longitudinal cross-sectional view schematically showing an advantage of the semiconductor manufacturing method according to the sixth embodiment of the present invention; and

FIG. 17 is a longitudinal cross-sectional view schematically showing a problem in a semiconductor chip included in a semiconductor device according to a conventional technique.

### DESCRIPTION OF THE PREFERRED EMBODIMENTS

### First Embodiment

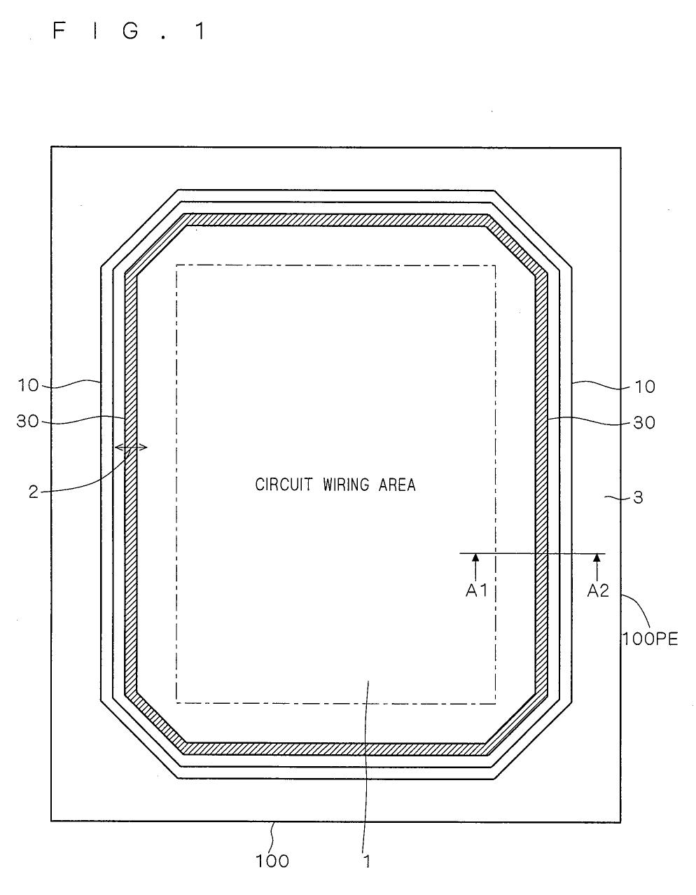

FIG. 1 is a plan view schematically showing the structure of a semiconductor chip 100 included in a semiconductor device according to a first embodiment. As shown in FIG. 1, a seal ring 30 made of a metal wall is disposed so as to entirely circle around a circuit wiring area (corresponding to an effective element area inside the chip) 1. In a chip outer area 3 outside a seal ring area 2 provided with the seal ring 30, an air gap 10 is provided so as to circle around the seal ring 30 in a loop along the outer wall of the seal ring 30. The existence of the air gap 10 provided in the chip outer area 3 constitutes the core part of the present embodiment. It should be noted that reference numeral 100PE denotes the peripheral edge of the semiconductor chip 100.

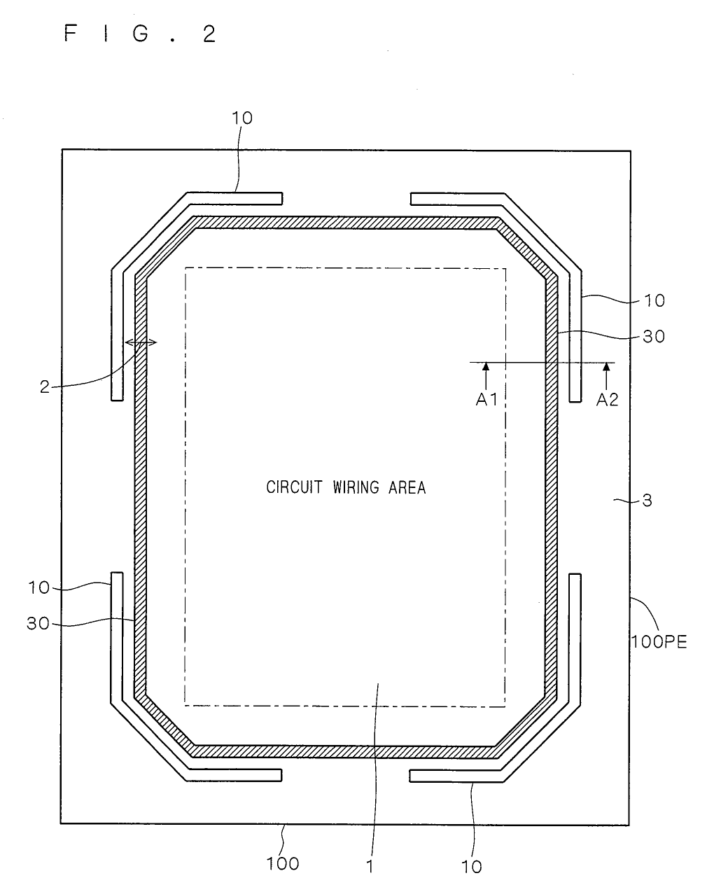

FIG. 2 corresponds to a modification of the structure of FIG. 1 and shows a structure in which air gaps 10 are disposed partly along the outer wall of the seal ring 30 in the chip outer area 3. In this case, each air gap 10 partly surrounds the seal ring 30 on the outer side thereof.

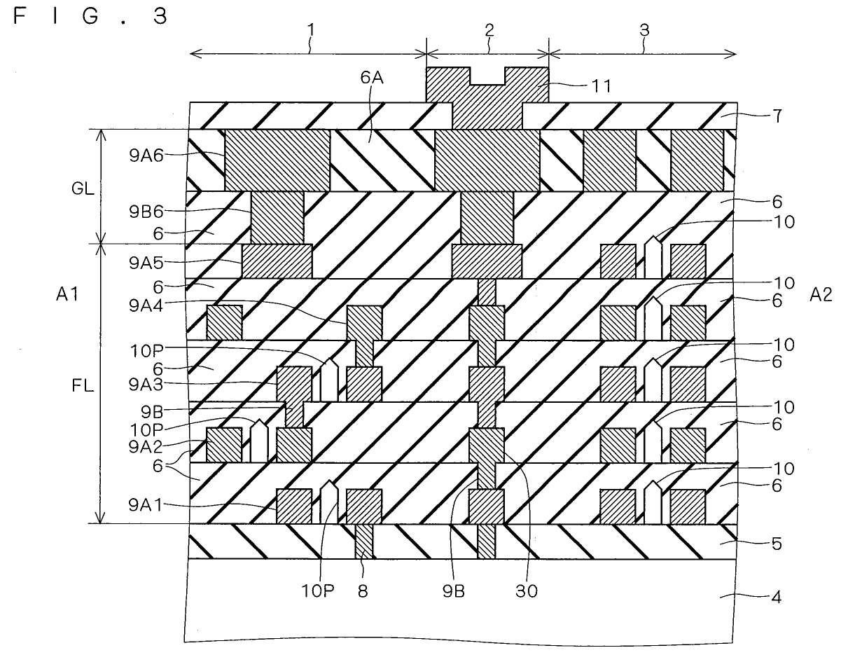

FIG. 3 is a diagram showing a longitudinal cross-sectional structure of the present semiconductor chip taken along line A1-A2 of FIG. 1 or 2. In FIG. 3, the structures in the chip inner area 1 and the seal ring area 2 are the same as those of the corresponding areas in the conventional semiconductor chip. A detailed description is given below.

A contact interlayer dielectric 5 made of, e.g., a TEOS film or an OSG film is provided over the top surface of an Si substrate 4. The contact interlayer dielectric 5 is provided with contact holes, which contact holes are fully filled with contact layers 8. The contact layers 8 are a metal layer formed of a plug layer made of, e.g., W and a barrier metal formed around the plug layer. The contact layers 8 provide electrical connection between hard-wires 9A1 in a first layer and the Si substrate 4 or transistors (not shown) and Cu is not used as a material of the contact layers 8 in order to prevent diffusion of Cu into the Si substrate 4. In addition, since the capacitance of the contact interlayer dielectric 5 does not have much effect on the processing speed of signals, and besides, for the purpose of forming contact holes in a favorable manner by means of etching while improving an embedding property of transistors, a low-permittivity film is usually not used for the contact interlayer dielectric 5. Accordingly, the contact interlayer dielectric 5 is sufficiently strong and does not cause a problem of defect due to a crack, which is the subject of the present invention.

Between a top surface of the contact interlayer dielectric 5 and an interlayer dielectric 6A (made of, e.g., an FSG film, a TEOS film, or an HDP oxide film) directly under an insulating film 7 (made of, e.g., SiN film) of a pad contact layer provided are first insulating films 6 as interlayer dielectrics covering hard-wires and the like in each wiring layer. It should be noted that an air gap 10 to be described later is not disposed within the first insulating film 6 in the area of a global wiring layer GL to be described later. The permittivity of the first insulating films 6 is lower than the permittivity of the contact interlayer dielectric 5 from the above-described viewpoint of attaining high speeds through wiring, and the first insulating films 6 are made of a so-called low-k film. Specifically, the first insulating films 6 are made of an inorganic material such as MSQ or SiOC or an organic resin material. In short, many kinds of low-k films can be used for the first insulating films 6.

Wiring layers relative to the thickness direction or the deposition direction of the first insulating films 6 are roughly divided into the global wiring layer GL including hard-wires 9A6 that locate in the uppermost layer and via layers 9B6 filling up via holes, and a fine wiring layer FL under the global wiring layer GL. Among these layers, the hard-wires 9A6 in the global wiring layer GL function as, e.g., electrode wiring, and on a top surface of a hard-wire in the uppermost layer of the seal ring 30 in the global wiring layer GL disposed is a pad metal layer 11 made of, e.g., Al containing Cu by 1 wt % or less. In this manner, wiring for power supply and the like are often laid out in the uppermost layer, and in order to reduce resistance therefor, in the global wiring layer GL, the hard-wires 9A6 located in the uppermost layer and the via layers 9B6 are wide and deep as compared with the hard-wires and via layers in the fine wiring layer FL. And besides, the interlayer dielectric 6A between the adjacent hard-wires 9A6 in the uppermost layer is not a low-k film as described earlier, and the hard-wires 9A6 located in the uppermost layer and the via layers 9B6 are made of, e.g., Cu containing Al by 1 wt % or less. Consequently, it is not necessary to provide an air gap 10 to be described later in the interlayer dielectric 6A between adjacent hard-wires 9A6 in the uppermost layer that are in the outer area of the seal ring 30 in the global wiring layer GL.

An exemplary structure of each wiring layer in the fine wiring layer FL is described below with reference to FIG. 3. On the top surface of the contact interlayer dielectric 5 disposed are first hard-wires 9A1 (made of Cu) that constitute wiring in a first wiring layer. Also, in the chip inner area 1, an air gap 10P is provided as in the conventional technique. The air gaps 10 and 10P between the first hard-wires 9A1 and within the first wiring layer are covered with a first insulating film 6, which is a low-k film. A second wiring layer directly over the first wiring layer is disposed with a via layer 9B (made of Cu) constituting a part of the seal ring 30, second hard-wires 9A2 (made of Cu), and an air gap 10P as in the conventional technique. These second hard-wires 9A2 and the like are covered with a first insulating film 6, which is a low-k film. A third wiring layer further thereover is disposed with third hard-wires 9A3 (made of Cu), a via layer 9B (made of Cu) connected with any of the third hard-wires 9A3, and an air gap 10P as in the conventional technique. These third hard-wires 9A3 and the like are covered with a first insulating film 6, which is a low-k film. A fourth wiring layer further thereover is disposed with fourth hard-wires 9A4 (made of Cu) and a via layer 9B (made of Cu) connected with any of the fourth hard-wires 9A4, and the fourth hard-wires 9A4 and the like are covered with a first insulating film 6, which is a low-k film. A fifth wiring layer further thereover is disposed with fifth hard-wires 9A5 (made of Cu) and a via layer 9B (made of Cu) constituting a part of the seal ring 30, and the fifth hard-wires 9A5 and the like are covered with a first insulating film 6, which is a low-k film. In this manner, in the structural example of FIG. 3, the five wiring layers of the first to fifth wiring layers, each including Cu hard-wires and at least one Cu via layer, are disposed in the fine wiring layer FL along the thickness direction or the deposition direction of the first insulating films, which are a low-k film. It should be noted that some modern semiconductor devices include as many as around ten wiring layers in their fine wiring layers FL.

In each of the wiring layers, the seal wing 30 is provided so as to enclose the chip inner area (effective element area) 1. The seal ring 30 is provided for the purpose of shutting out moisture from the inside of the semiconductor chip. Accordingly, in order to completely shut out moisture from the effective element area, the seal ring 30 is provided circling around the chip inner area (effective element area) 1 in a loop. The seal ring 30 is usually formed in the same process as the hard-wires and the via layers, and a wiring material is fully embedded in the holes for the hard-wires and the via layers. Usually, Cu (and a barrier metal for preventing diffusion of Cu) are used as a material for the seal ring 30 in order to provide low resistance; however, like the contact layers 8, W is often used instead of Cu as the material for a portion of the seal ring 30 that is provided in the contact interlayer dielectric 5.

As the core structure of the present embodiment, on the assumption that a crack occurs due to the dicing process and the like in a direction from the peripheral edge 100PE toward the inner side in the semiconductor chip 100 of FIG. 1, a plurality of layers of air gaps 10 are arranged within the first insulating films 6 and inside the chip outer area 3 from the seal ring area 2 provided with the seal ring 30 up to the peripheral edge 100PE of the semiconductor chip 100. That is, a portion of the first insulating film 6 (each separation distance therefor is of from e.g., 65 nm to 70 nm) between each two adjacent hard-wires 9Ai (i is an integer in the range of 1 to 5; the wire width of the hard-wires 9Ai is, e.g., in the range of 65 nm to 70 nm) that are disposed in each of the wiring layers of the first to fifth wiring layers is provided with an air gap 10, which is a space or a hole that is extended parallel to the thickness direction of each first insulating film 6 and is hermetically closed with the space being, e.g., in a vacuum state. The air gaps 10 in the respective wiring layers are arranged in a line along the thickness direction of the first insulating films 6 so as to be parallel to the seal ring 30. The structural body constituted by the plurality of (five herein) of air gaps 10 that are arranged in a line along the thickness direction of the first insulating films 6 is defined as “one air gap structure” in the following description. It should be noted, in the present embodiment, the air gaps 10 may be formed through any technique. Also, although in FIG. 3 the pad interlayer film 7 and the pad metal layer 11 are located on the uppermost layer, there are a variety of kinds of pad structures, and any structure may be used as the pad structure in the present embodiment. The adjacent hard-wires 9Ai in the chip outer area 3 are dummy metal and usually do not function as an electric circuit. Further, the hard-wires 9Ai (i is an integer in the range of 1 to 5) that are in the chip inner area 1 and not connected with the via layers 9B are dummy metal, which serve to prevent the hard-wires 9Ai that are in the chip inner area 1 to function as an electric circuit from being dished by the CMP process as well as to equalize respective occupancies of metal in the layers. Advantages of disposing one air gap structure outside the seal ring 30 are described below with reference to the drawings.

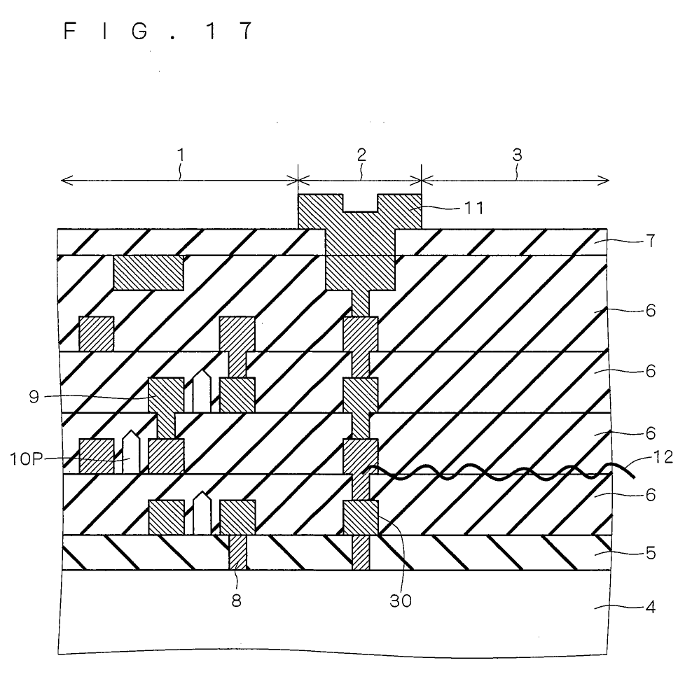

In the conventional technique, when a crack 12 occurs in dicing, packaging, or the like, the crack 12 reaches the seal ring 30, so that the seal ring 30 is damaged (FIG. 17); therefore, the seal ring 30 becomes unable to fulfill the required water proofing function, bringing the result that moisture enters the semiconductor chip.

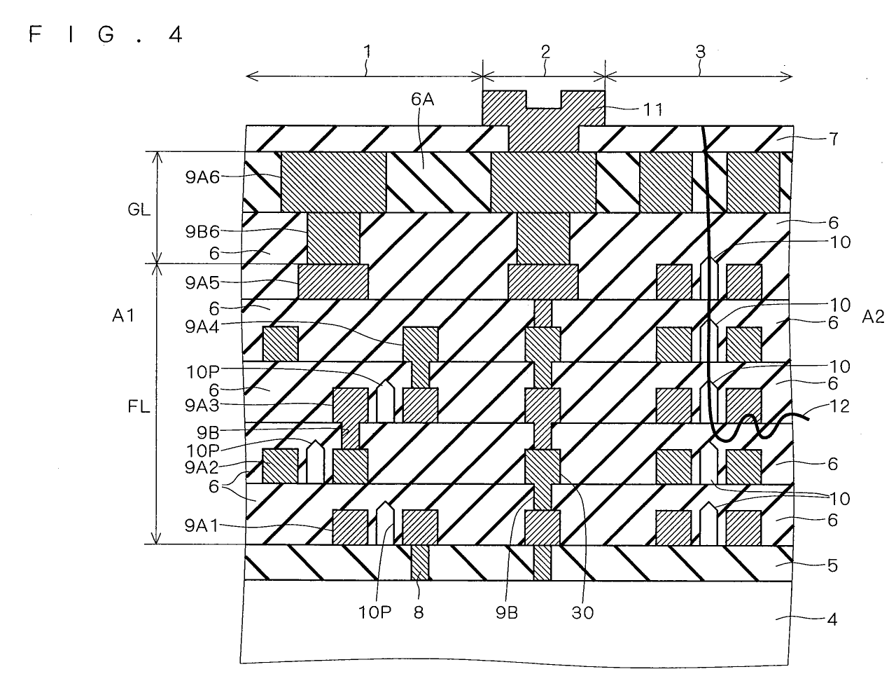

In contrast, in the present embodiment, one air gap structure comprised of a plurality of layers of air gaps 10 exists in the outer area 3 of the seal ring 30, as described above. If a crack is produced due to dicing or the like, as schematically shown in FIG. 4 based on the longitudinal cross-sectional view of FIG. 3, the crack 12 reaches an air gap 10, but the air gap 10 changes the direction in which the crack 12 advances to an upward direction. This is because, while a certain level of force (energy) is necessary to break the first insulating films 6 in the course of propagation of the crack 12, in a case where the crack 12 advances in the direction along which the air gaps 10 are lined, the air gaps 10 can be broken with lesser force (energy) because of the structure of the air gaps 10 which are originally holes. Accordingly, the advancing direction of the crack 12 is changed to the thickness direction or the longitudinal direction of the first insulating films 6, along which direction the air gaps 10, which are more breakable than the first insulating films 6, are lined.

What is more, in the present embodiment, as illustrated in FIG. 3, since the air gaps 10 are arrayed in the longitudinal direction continuously across the plurality of wiring layers, the crack 12, as illustrated in FIG. 4, advances one after another through the upwardly-lined air gaps 10 that are easily breakable, outside the seal ring 30 and in parallel to the seal ring 30. Accordingly, the crack 12 is unable to reach the seal ring 30, so that a defect caused by damage of the seal ring 30 cannot occur. Moreover, the provision of dummy metal helps equalizing the respective occupancies of metal in the layers, whereby circuit layout rules can easily be satisfied; therefore, chips can be easily designed, and as shown in FIG. 4, a structure can be achieved in which the crack 12 passes through an interface between the dummy metal and the associated first insulating film 6 and which permits the crack 12 to advance more easily through the air gaps 10 provided between dummy metal portions.

An advantage can be recognized in providing at least one air gap 10 in the chip outer area 3 to change the advancing direction of the crack 12 to the extending direction of that air gap 10.

### Second Embodiment

The present embodiment relates to a method of manufacturing the air gap structure shown in the first embodiment. In particular, a feature thereof resides in the simultaneous formation of the air gap 10P in the chip inner area (effective element area) 1 and the air gap 10 in the chip outer area 3 outside the seal ring in the same process. By forming both the air gaps 10 and 10P simultaneously, the targeted air gap structure can be formed without increasing the number of processes.

An exemplary method of forming the air gaps 10 is described below. According to the manufacturing method illustrated below, an interlayer dielectric is etched through a dry etching process using hard-wires as masks, and an insulating film is formed so as to make a hermetically-closed hole in a groove provided between adjacent hard-wires, thereby forming an air gap 10. In the following description, although a first insulating film 6 to be an interlayer dielectric is made of a single kind of low-k film, the present invention is not limited thereto, and the first insulating film 6 may be formed of a plurality of kinds of low-k films. In this case also, the above-described advantages can be obviously provided likewise.

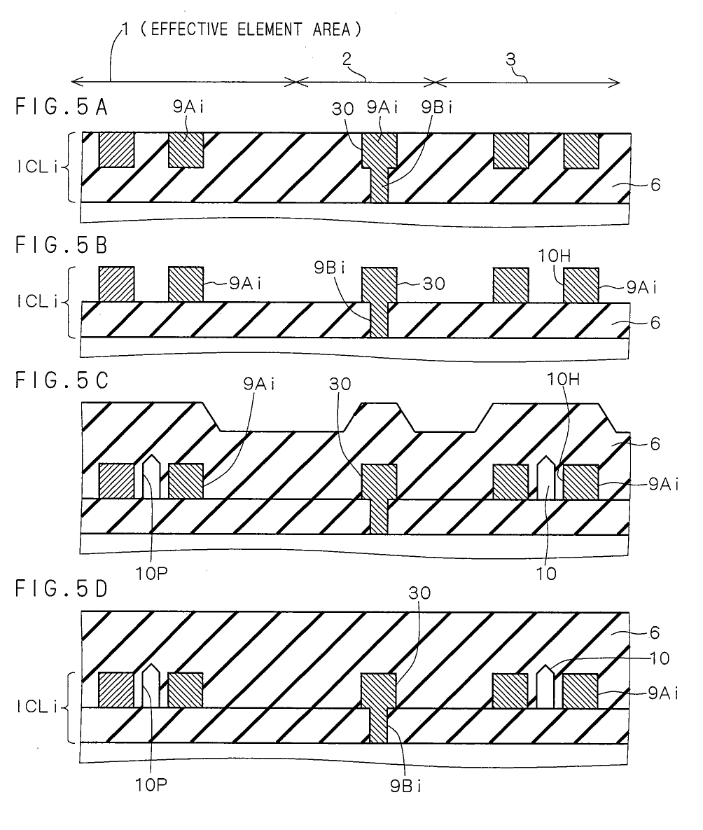

In this embodiment, an i-th wiring layer ICLi (i is an integer of or larger than 1) is considered as a starting point in the description of the manufacturing method. A first insulating film 6 or a contact interlayer dielectric 5 (when i=1) is formed on the top surface of the first insulating film 6 in an (i−1)-th wiring layer or the Si substrate 4 (when i=1). Then, according to the usual dual-damascene formation flow, a via hole to be filled with a via layer and wiring grooves to be filled with hard-wires of Cu are formed in the effective element area 1, a groove to be provided with the seal ring 30 is formed in the seal ring area 2, and adjacent grooves are formed in the outer periphery portion of the seal ring 30 inside the chip outer area 3, followed by filling up the respective grooves with metal (e.g., Cu and a barrier metal). In the case of i=1, a via hole to be provided with the seal ring 30 out f the grooves is filled with W and its barrier metal in place of Cu and its barrier metal. After that, surplus metal is removed by means of the CMP process or the like, thereby forming hard-wires 9Ai, a via layer 9Bi, and dummy metal portions in the i-th wiring layer ICLi (see FIG. 5A).

Subsequently, by using the metal of the hard-wires 9Ai as masks, the first insulating film 6 in the i-th wiring layer ICLi is etched to expose the respective hard-wires 9Ai (see FIG. 5B). Through this process, a groove 10H to be provided with an air gap 10 to be described later is formed between adjacent hard-wires 9Ai in the chip outer area 3.

Next, a first insulating film 6 with low step coverage is deposited over the first insulating film 6 that is a barrier insulating film, thereby simultaneously forming air gaps 10 and 10P between adjacent Cu hard-wires 9Ai, which air gaps are holes hermetically closed in a vacuum state without being deposited with the first insulating film 6 (see FIG. 5C). In this process, the air gap 10 is formed in the groove 10H on the outer peripheral side of the seal ring simultaneously with the formation of the air gap 10P.

Subsequently, the deposited first insulating film 6 is planarized through the CMP process, thereby forming a first insulating film 6 as an interlayer dielectric in an (i+1)-th wiring layer (see FIG. 5D).

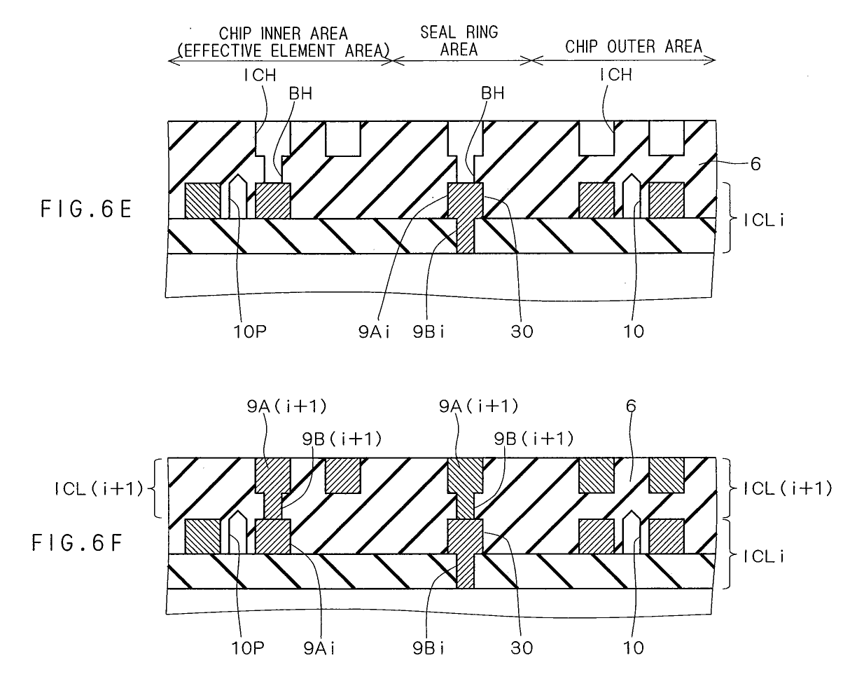

After that, according to the usual damascene method, a via hole BH and grooves ICH to be filled with hard-wires are formed in the chip inner area 1 which is the effective element area, grooves BH and ICL are formed to be provided with the seal ring, and adjacent grooves ICH are formed on the outer periphery side of the seal ring in the chip outer area 3 (see FIG. 6E).

Finally, metal (e.g., Cu) is embedded in the corresponding grooves, and surplus metal is removed by means of CMP, whereby an (i+1)-th wiring layer ICL(i+1) is completed (see FIG. 6F). As shown in FIG. 6F, the (i+1)-th wiring layer ICL(i+1) includes via layers 9B(i+1) and hard-wires 9A(i+1). The seal ring 30 is constituted by a combination of metal layers 9Bi, 9Ai, 9B(i+1), and 9A(i+1), in the i-th wiring layer ICLi and the (i+1)-th wiring layer ICL(i+1).

The above-described processes are repeated a desired number of times to form the semiconductor device described in the first embodiment. In this manner, the dummy metal portions provided in the chip outer area 3 allow the targeted air gap 10 to be formed easily.

It should be noted that it is basically possible to apply the technical concept of the manufacturing method described above to third to sixth embodiments to be described hereinafter.

There are a plurality of methods of forming air gaps, such as evaporation of sacrificial films, other than the above manufacturing method. According to the present invention, a similar effect can be obtained through methods other than the exemplified manufacturing method.

### Third Embodiment

A feature of the present embodiment resides in the provision of a plurality of air gap structures in the vicinity of the seal ring 30 in the chip outer area 3, instead of the “one air gap structure” described in the first embodiment. That is, a plurality of air gap structures constitute the air gap structure disposed in an outer portion of the seal ring 30. Other components are the same as in the first embodiment. The feature of the present embodiment is described below with reference to the drawings.

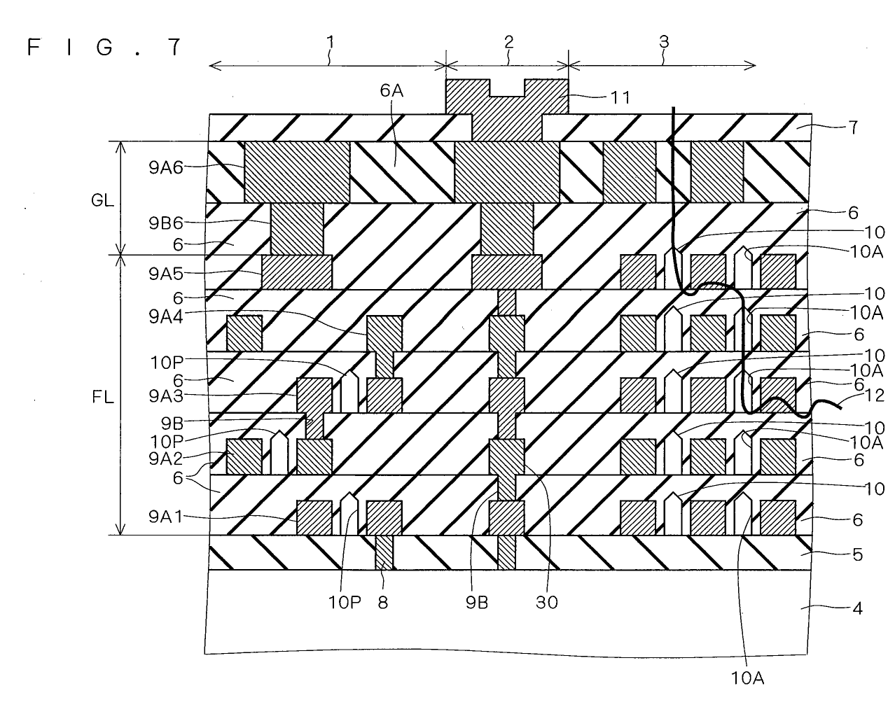

FIG. 7 corresponds to FIG. 3 and shows a longitudinal cross-sectional view of the structure of a semiconductor chip 100 according to the present embodiment. FIG. 7 is different from FIG. 3 in the following points. That is, in the example of FIG. 3, in the vicinity of the seal ring 30 only disposed is a first air gap structure constructed by arranging first air gaps 10 into a line along the thickness direction of the first insulating films 6. Meanwhile, in FIG. 7, a second air gap structure is disposed on a further outer side of the first air gap structure so as to extend parallel to the first air gap structure in the thickness direction of the first insulating films 6. The second air gap structure is constructed such that a second air gap 10A, which is identical to the first air gaps 10 in shape and size, is provided within each of the wiring layers, and the second air gaps 10A are arranged in a line along the thickness direction of the first insulating films 6. Of course, instead of the structure of FIG. 7, more than two air gap structures may be provided. Hard-wires 9Ai (i is an integer in the range of 1 to 5) in the chip outer area 3 are dummy metal and do not usually function as an electric circuit. Moreover, the hard-wires 9Ai (i is an integer in the range of 1 to 5) that are in the chip inner area 1 and not connected with via layers 9B are dummy metal. Advantages of the present embodiment having such a structure are as follows.

That is, in the first embodiment, the first air gaps 10 change the advancing direction of the crack 12 to an upward direction to thereby prevent the seal ring 30 from being damaged by the crack 12; however, if the advancing direction of the crack 12 is again changed to a lateral direction toward the seal ring 30 by some effect, there is a possibility that the crack 12 reaches the seal ring 30. In contrast, since a plurality of air gap structures are provided in the present embodiment, even if the advancing direction of the crack 12 changes to a lateral direction, the air gaps cause the advancing direction to be changed again to an upward direction, so that the seal ring 30 can be kept from intrusion of the crack 12 (see FIG. 7). While FIG. 7 illustrates an example in which two air gap structures are provided, a further enhanced protection effect can be expected by providing more than two air gap structures. It should be noted that since each of the air gaps 10 and 10A can be formed with a minimum wire width and a minimum separation distance, providing a plurality of air gap structures does not require so much area.

### Fourth Embodiment

A feature of the present embodiment resides in that the number i of air gap structures disposed at corner portions (corners) of a semiconductor chip is larger than the number j of air gap structures disposed in other portions (particularly in portions parallel to side surfaces of the semiconductor chip) (i>j). In the following description, the feature of the present embodiment and advantages thereof are described with reference to the drawings.

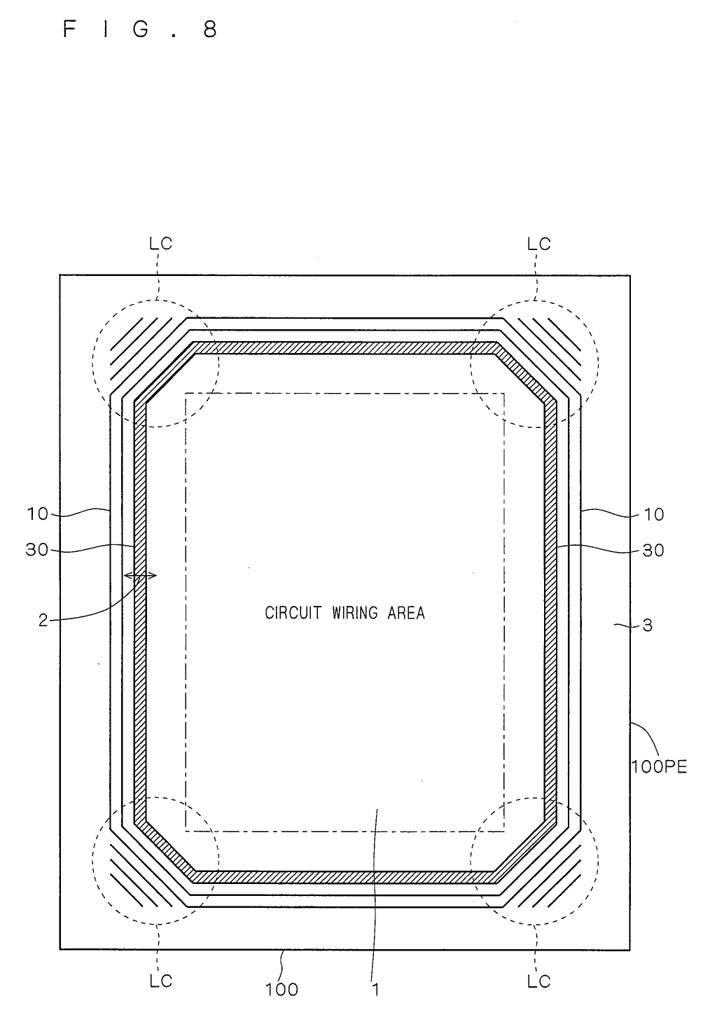

FIG. 8 is a plan view of a semiconductor chip 100 included in a semiconductor device according to the present embodiment and corresponds to the above-described FIG. 1. FIG. 8 is different from FIG. 1 in the (number of) disposition of air gap structures in areas LC closed with broken lines in FIG. 8.

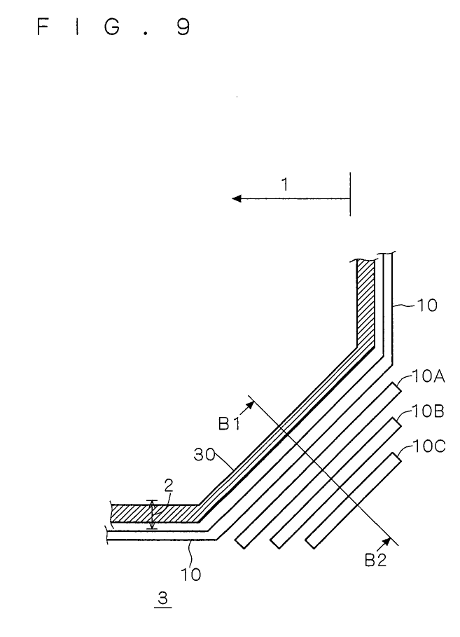

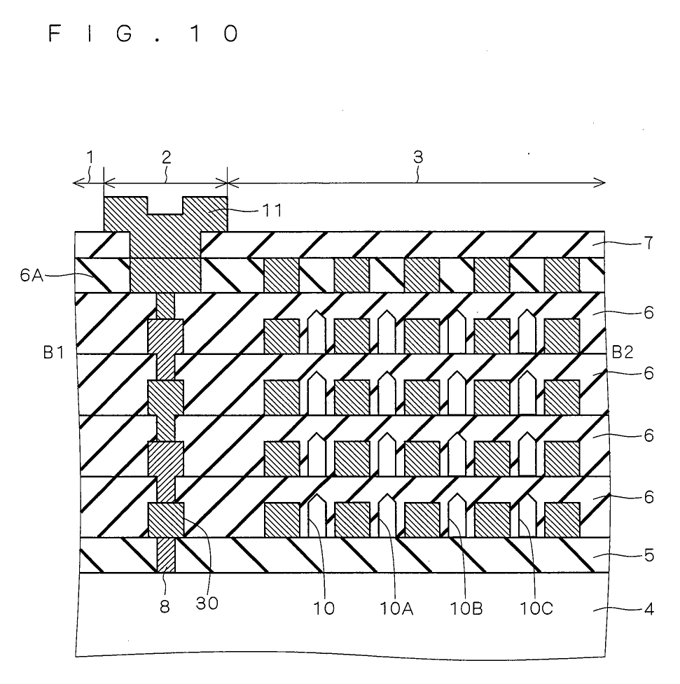

FIG. 9 is an enlarged plan view of an area LC, which is a corner, shown in FIG. 8. FIG. 10 is a longitudinal cross-sectional view showing the structure taken along line B1-B2 in FIG. 9. As illustrated in FIGS. 9 and 10, in the chip outer area 3 at a corner of the semiconductor chip 100, four air gap structures are disposed sequentially at predetermined intervals, in the vicinity of the outer side of the seal ring 30. That is, a first air gap structure is constructed by arranging respective first air gaps 10 within the wiring layers into a line along the thickness direction of the first insulating films 6, and the first air gap structure (i.e., each first air gap 10) entirely surrounds the outer wall of the seal ring 30 in a loop. A second air gap structure adjacent to the first air gap structure is constructed by arranging respective second air gaps 10A within the wiring layers into a line along the thickness direction of the first insulating films 6 and faces an outer wall portion of the seal ring 30 at a corner. Further, a third air gap structure adjacent to the second air gap structure is constructed by arranging respective third air gaps 10B within the wiring layers into a line along the thickness direction of the first insulating films 6 and faces likewise the outer wall portion of the seal ring 30 at the corner with the first and second air gap structures interposed therebetween. Furthermore, on the outer side thereof disposed is a fourth air gap structure constructed by arranging respective fourth air gaps 10C within the wiring layers into a line along the thickness direction of the first insulating films 6. The longitudinal size of the fourth air gap structure along the extending direction of the seal ring 30 at the corner is the shortest of those of the other air gap structures, in view of the positional relationship in disposing them. The hard-wires 9 in the chip outer area 3 are dummy metal.

Meanwhile, in the present example shown in FIGS. 8 and 9, one air gap structure is disposed so as to oppose outer wall portions of the seal ring 30 that face the side surfaces of the semiconductor chip 100.

Advantages of the present embodiment are as follows. That is, the reason why a crack occurs due to packaging is that there is a difference in level of stress between the first insulating films 6 constituting the semiconductor chip and a resin in which the semiconductor chip is sealed in packaging, which stress is higher in the resin; consequently, strong stress occurs in the first insulating films 6 in response to a change in operation temperature and the like, inviting peeling off of a first insulating film 6. The stress from the resin is the highest at corners of the semiconductor chip 100. Thus, cracks are most likely to occur at the corners of the semiconductor chip. In the dicing process also, the corners of a semiconductor chip are subjected to impact force twice, namely, the impact force caused by longitudinal dicing and the impact force caused by lateral dicing, and therefore, the corners of a semiconductor chip are most liable to cracks. In this regard, since a plurality of air gap structures are disposed within the first insulating films 6 at the corners of the semiconductor chip in the present embodiment, even if a crack 12 occurs at a corner of the semiconductor chip, the crack 12 hardly reaches the seal ring 30.

### Fifth Embodiment

The present embodiment proposes a structure preventive of production of a crack 12 within the first insulating films 6 from the peripheral portion 100PE of the semiconductor chip 100 toward the seal ring 30, even in the case where stress is inflicted around the peripheral portion 100PE from the resin by packaging. In short, the structural core of a semiconductor chip of a semiconductor device according to the present embodiment is the provision of at least one air gap structure in each of a proximate portion of the outer wall of the seal ring 30 and a proximate portion of the peripheral portion 100PE where dicing is conducted, within the first insulating films 6 in the chip outer area 3. Of course in the present embodiment also, none of the air gaps is formed within the first insulating films 6 in the global wiring layer GL (see FIG. 3) as in the foregoing first to fourth embodiments, from the viewpoint of unnecessity. Also, the one air gap structure in each of the proximate portions may be constructed of at least one air gap. In that case, however, it is necessary that the associated air gaps in each of the proximate portions should belong to the same wiring layer. The structure of the core part of the present embodiment and advantages thereof are described below with reference to the drawings.

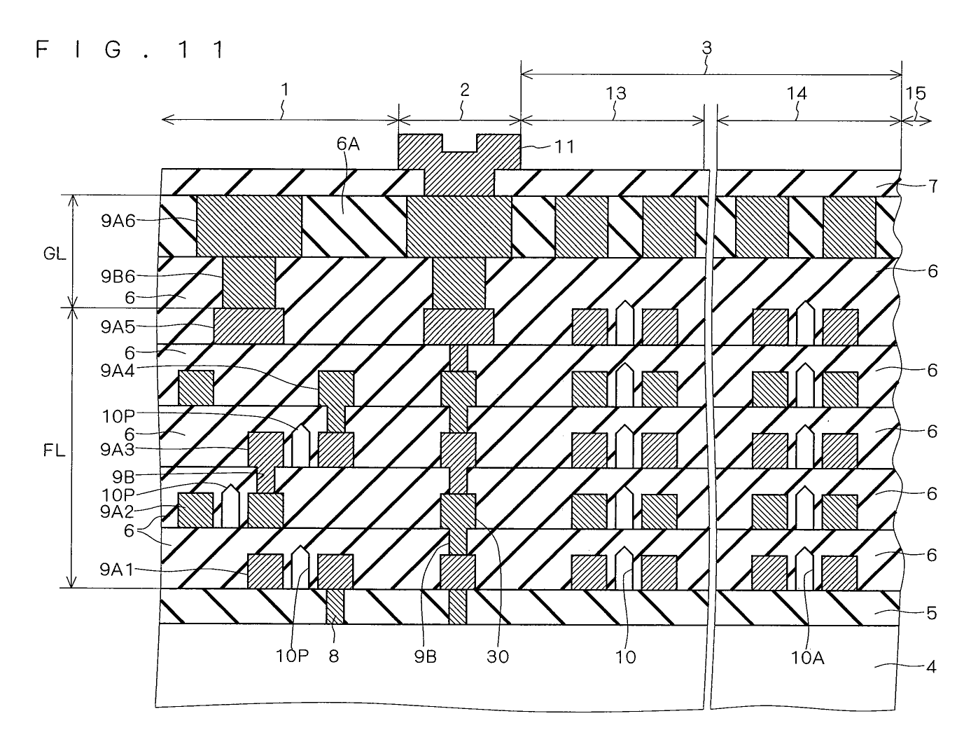

FIG. 11 is a longitudinal cross-sectional view of the structure of a semiconductor chip included in a semiconductor device according to the present embodiment. In FIG. 11, the chip outer area 3 outside the area 2 of the seal ring 30 includes a seal ring proximate area 13 inside the chip outer area 3 and a dicing proximate area 14 inside the chip outer area 3, and the peripheral portion 100PE of a semiconductor chip 100 and the further outer area thereof are, in FIG. 11, defined as an area 15 that has been cut off by dicing.

As shown in FIG. 11, the seal ring proximate area 13 inside the chip outer area 3 is provided with one first air gap structure parallel to and opposite the outer wall of the seal ring 30 within the first insulating films 6. As described above, the respective air gaps 10 provided in the wiring layers are disposed within the first insulating films 6 in the proximate area of the seal ring 30 and are hermetically-closed holes that are extended parallel to the thickness direction of the first insulating films 6. The one first air gap structure may desirably entirely surround the outer wall of the seal ring 30 in a loop as shown in FIG. 1, or alternatively, may partly surround the outer wall of the seal ring 30 as shown in FIG. 2.

Moreover, as shown in FIG. 11, in the area around the outer wall of the seal ring 30, one second air gap structure is disposed within the first insulating films 6 in the dicing proximate area 14 inside the chip outer area 3, so as to be parallel to and opposite the outer wall of the seal ring 30 with the first air gap structure interposed therebetween. As described above, the respective air gaps 10A provided in the wiring layers are disposed within the first insulating films 6 in the area proximate to the peripheral edge of the semiconductor chip. And besides, the respective air gaps 10A are hermetically-closed holes that are extended parallel to the thickness direction of the first insulating films 6 and are disposed in the same wiring layers as their respective associated first air gaps 10. Obviously, the one second air gap structure may desirably entirely surround the outer wall of the seal ring 30 in a loop as shown in FIG. 1, or alternatively, may partly surround the outer wall of the seal ring 30 as shown in FIG. 2. The hard-wires 9Ai (i is an integer in the range of 1 to 5) in the chip outer area 3 are dummy metal and usually do not function as an electric circuit. In addition, the hard-wires 9Ai (i is an integer in the range of 1 to 5) that are in the chip inner area 1 and not connected with via layers 9B are dummy metal.

The width size of each of two hard-wires sandwiching each of the air gaps 10 and 10A with a first insulating film 6 interposed therebetween is set, e.g., to a value of from 65 nm to 70 nm as described earlier, whilst the distance from an end of the seal ring area 2 to an end of the dicing proximate area 14 outside the chip is set to a value of from 10 μm to 20 μm. Accordingly, it is possible to dispose the first and second air gap structures with a sufficient allowance within the first insulating films 6 that are located in the area between the end of the seal ring area 2 and the end of the dicing proximate area 14 outside the chip.

Obviously, it is possible to provide a plurality of first air gap structures and a plurality of second air gap structures.

Advantages of the present embodiment are as follows.

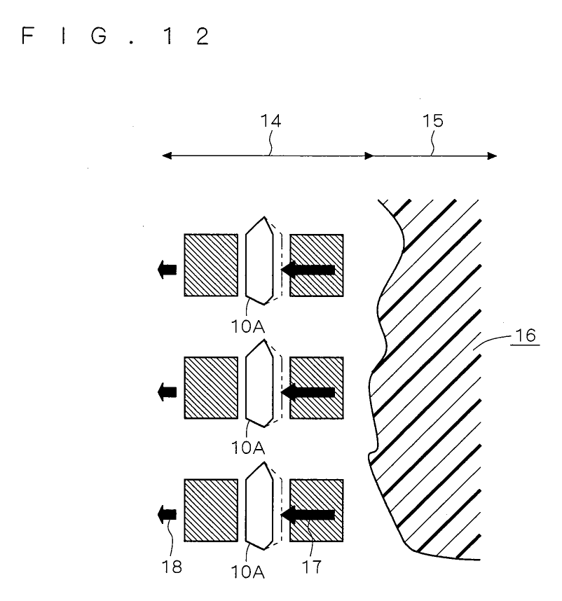

A first insulating film 6 peels off due to packaging in such a way that, as described earlier, stress is inflicted thereon from the resin. In the present embodiment, as described above, the second air gaps 10A exist within the first insulating films 6 in the area 14 proximate to the area 15 where dicing has been performed. Accordingly, as shown schematically in the plan view of FIG. 12, the second air gaps 10A are, because of their structures as hermetically-closed cavities, easily deformed in response to stress 17 applied from a resin 16 during packaging. When the second air gaps 10A are deformed as shown in FIG. 12, the stress 17 is relieved by the deformation, so that relieved stress 18 to be transmitted from the second air gap structure to the inside of the semiconductor chip is far less than the stress 17 that is applied from the resin 16. Thus, a crack 12 is less likely to occur within the first insulating films 6 in the chip outer area 3. Moreover, the first air gaps 10 absorb the relieved stress 18, whereby the stress from the resin 16 disappears, and such a crack 12 that may reach the seal ring 30 does not occur.

It should be noted that, by providing a plurality of second air gap structures that are comprised of the second air gaps 10A disposed in the area 14 proximate to the area where dicing has been performed, the above stress-relief effect can be further enhanced.

### Sixth Embodiment

The core part of a method of manufacturing a semiconductor device according to the present embodiment lies in that, in a case of using laser dicing, air gaps are provided in advance in portions of the wiring layers within the first insulating films on a dicing line for a semiconductor wafer, whereupon an Si substrate is melted by laser dicing to cleave the wiring layer portions. The manufacturing method according to the present embodiment and advantages thereof are described below with reference to the drawings.

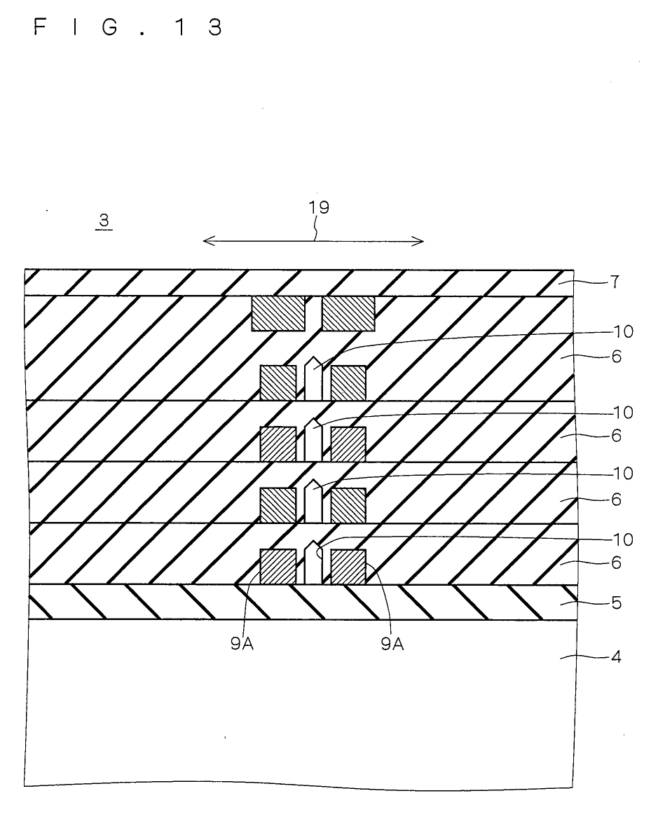

FIG. 13 is a longitudinal cross-sectional view showing in an enlarged manner a portion to be subjected to laser dicing, of a semiconductor wafer in which a circuit wiring area (not shown), a seal ring (not shown), and the like are provided on an Si substrate. As illustrated in FIG. 13, within the first insulating films 6 located in an area 19 to be irradiated with a laser beam, an air gap 10 is provided, sandwiched by adjacent hard-wires with a first insulating film 6 interposed therebetween, in each of the wiring layers other than the portion corresponding to the global wiring layer. These air gaps 10 constitute one air gap structure located on a dicing line portion. Hard-wires 9A are dummy metal and usually do not function as an electric circuit.

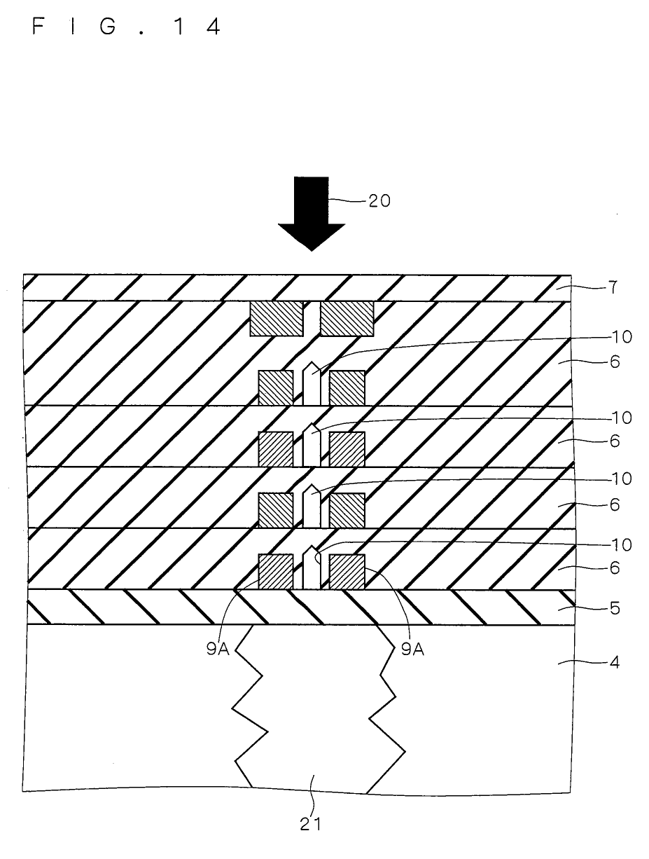

In the process of laser dicing, an optical wavelength capable of melting only an Si substrate 4 is chosen, and a laser beam 20 having that wavelength is emitted onto the dicing line portion on the semiconductor wafer, thereby melting a portion 21 of the Si substrate 4 that is directly under the dicing line portion, as schematically shown in the longitudinal cross-sectional view of FIG. 14.

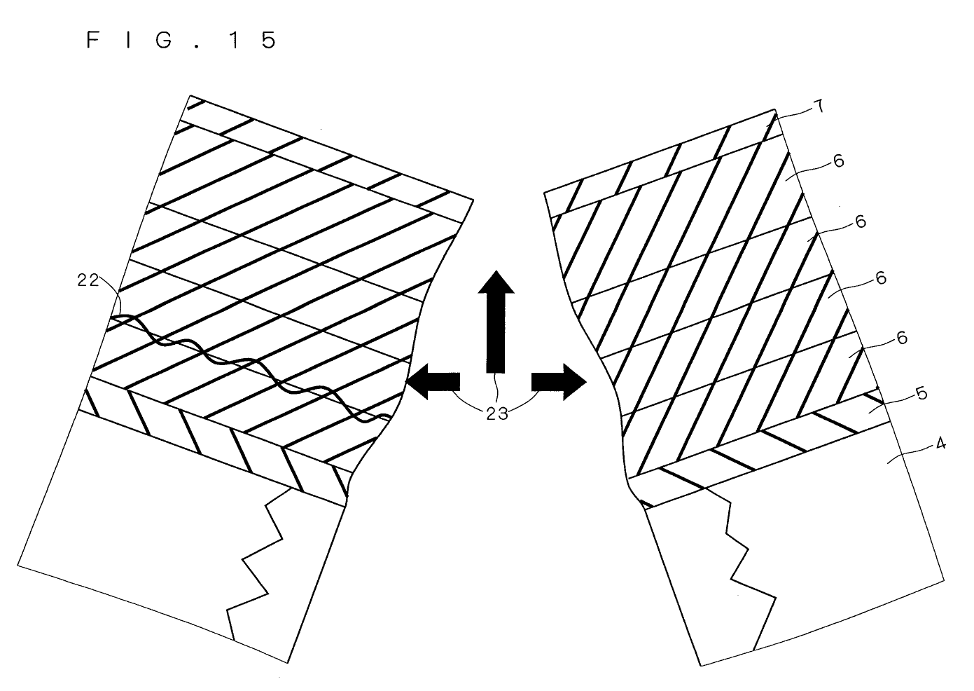

After that, cleavage is performed on the first insulating films 6 left on the portion 21 that has been melted through the application of the laser beam 20 out of the Si substrate 4 to separate a semiconductor chip from the semiconductor wafer. When cleavage is performed, however, strong stress 23 occurs in the first insulating films 6 on the melted portion 21, and as illustrated in FIG. 15, the stress 23 sometimes causes a crack 22 that runs into first insulating films 6 in the semiconductor chip.

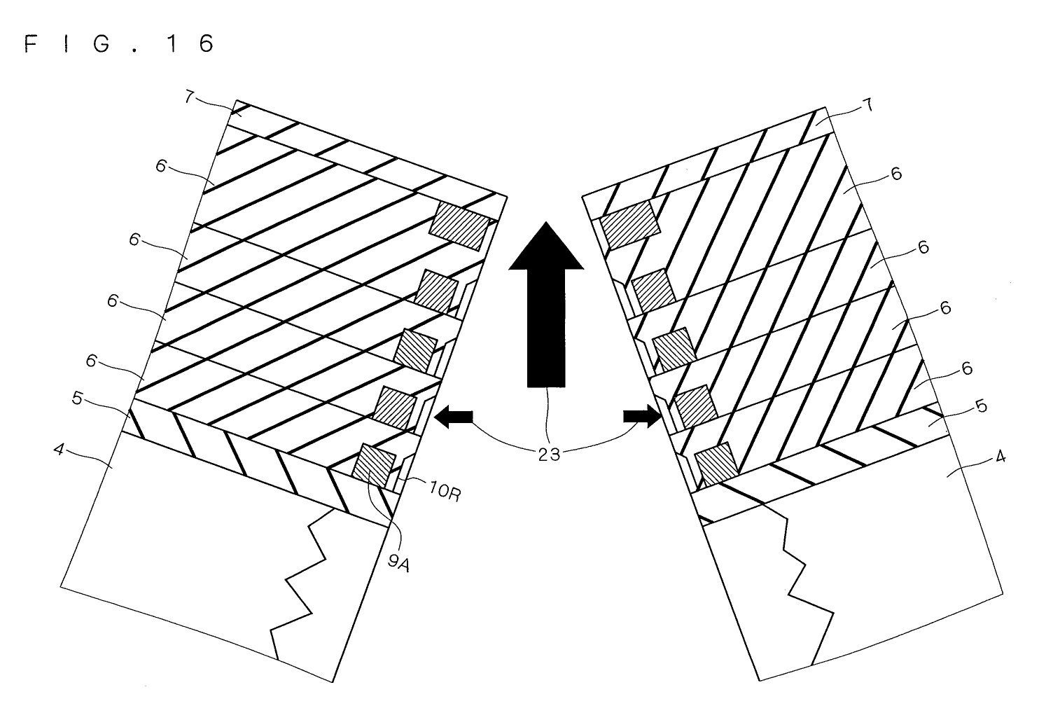

In the present embodiment, however, as shown in FIG. 13, the above-described air gap structure is provided in advance within the portions of the first insulating films 6 on the portion of the Si substrate to be melted through laser dicing. In this manner, in performing cleavage after laser dicing, since the air gaps 10, which are hermetically-closed holes or cavities, are provided within the portions of the first insulating films 6, which portions are directly on and over the melted area 21, the stress 23 primarily acts along the direction in which the air gaps 10, structurally weaker than the first insulating films 6, are arranged, so that the cleavage proceeds along the direction in which the air gaps 10 are arrayed in a line; therefore, in the cleavage, the stress 23 becomes relatively low in the direction toward the semiconductor chip, with the result that a crack is less likely to occur within the first insulating films 6 in the semiconductor chip (see FIG. 16). After the cleavage the peripheral end portion of the semiconductor chip is left with recessed portions 10R, which are the remainder of the air gaps 10 whose hermetically-closed structures have been broken by the stress 23.

The present invention can be suitably applied to, e.g., a semiconductor device including a semiconductor chip in which multiple-layered hard-wires in an effective element area (circuit wiring area) inside the semiconductor chip are formed through a damascene method, and in which first insulating films constituting interlayer dielectrics for wiring in the effective element area are formed of a low-k film that is lower in permittivity than a contact interlayer dielectric.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device comprising
a semiconductor chip including:
a semiconductor substrate;
a contact interlayer dielectric on a top surface of said semiconductor substrate;
a first insulating film on a top surface of said contact interlayer dielectric, said first insulating film having a lower permittivity than said contact interlayer dielectric; and
a seal ring provided, within said contact interlayer dielectric and within said first insulating film, along a thickness direction of said first insulating film from a lower surface of said contact interlayer dielectric up to an uppermost surface of said first insulating film, said seal ring encircling a circuit wiring area on said semiconductor substrate,
said semiconductor chip further including
at least one air gap within said first insulating film in a chip outer area from a seal ring area including said seal ring to a peripheral edge of said semiconductor chip, said air gap being extended parallel to said thickness direction of said first insulating film as well as being a hermetically-closed hole, wherein
two wires are provided within said first insulating film in said chip outer area with said air gap therebetween.

2. The semiconductor device according to claim 1, wherein
a plurality of air gaps each corresponding to said air gap are arranged in a line along said thickness direction of said first insulating film.

3. The semiconductor device according to claim 2, wherein
said semiconductor chip further includes a plurality of second air gaps provided within said first insulating film in said chip outer area and at outer positions of positions where said plurality of air gaps are disposed, said plurality of second air gaps arranged in a line along said thickness direction of said first insulating film and in parallel to said plurality of air gaps, and
each of said plurality of second air gaps is hermetically-closed hole extended parallel to said thickness direction of said first insulating film.

4. The semiconductor device according to claim 2, wherein
each of said plurality of air gaps is so disposed outside said seal ring as to entirely encircle said seal ring.

5. The semiconductor device according to claim 4, wherein
said semiconductor chip includes:
within said first insulating film in an area facing a corner of said semiconductor chip out of said chip outer area, based on a definition that said plurality of air gaps are a plurality of first air gaps, a plurality of i-th air gaps (i is an integer of or larger than 2) disposed at outer positions of positions where said plurality of air gaps are disposed, to be arranged in a line parallel to said plurality of air gaps along said thickness direction of said first insulating film, each of said plurality of i-th air gaps being a hermetically-closed hole extended parallel to said thickness direction of said first insulating film; and
within said first insulating film in an area facing a side surface of said semiconductor chip out of said chip outer area, based on the definition that said plurality of air gaps are the plurality of first air gaps, a plurality of j-th air gaps (j is an integer of or larger than 1) disposed at outer positions of the positions where said plurality of air gaps are disposed, said plurality of j-th air gaps arranged in a line parallel to said plurality of air gaps along said thickness direction of said first insulating film, each of said plurality of j-th air gaps being a hermetically-closed hole extended parallel to said thickness direction of said first insulating film, and
a relationship of i>j is established.

6. A semiconductor device comprising
a semiconductor chip including:
a semiconductor substrate;
a contact interlayer dielectric on a top surface of said semiconductor substrate;
a first insulating film on a top surface of said contact interlayer dielectric, said first insulating film having a lower permittivity than said contact interlayer dielectric; and
a seal ring provided, within said contact interlayer dielectric and within said first insulating film, along a thickness direction of said first insulating film from a lower surface of said contact interlayer dielectric up to an uppermost surface of said first insulating film, said seal ring encircling a circuit wiring area on said semiconductor substrate,
said semiconductor chip further including:
at least one first air gap within said first insulating film in an area proximate to said seal ring out of a chip outer area from a seal ring area including said seal ring to a peripheral edge of said semiconductor chip, said first air gap being extended parallel to said thickness direction of said first insulating film as well as being a hermetically-closed hole; and
at least one second air gap within said first insulating film in an area proximate to said peripheral edge of said semiconductor chip out of said chip outer area, said second air gap being extended parallel to said thickness direction of said first insulating film and disposed in the same wiring layer as said first air gap, as well as being a hermetically-closed hole, wherein
two wires are provided within said first insulating film in said chip outer area with said first air gap therebetween.

7. A method of manufacturing a semiconductor device comprising the steps of:
in an i-th wiring layer (i is an integer of or larger than 1), (1) when i is 1, forming a via layer within a contact interlayer dielectric on a top surface of a semiconductor substrate in a portion in a seal ring area to be provided with at least a seal ring, forming at least wires adjacent to each other on a portion of a chip inner area inside said seal ring area and on a portion of a chip outer area outside said seal ring area, within said contact interlayer dielectric, respectively and forming one wire identical to said wires on said via layer in said seal ring area, whereas (2) when i is 2 or larger, forming said via layer within a first insulating film above a top surface of said semiconductor substrate in a portion at least in said seal ring area, said first insulating film having a lower permittivity than said contact interlayer dielectric, forming at least wires adjacent to each other on a portion of said chip inner area and on a portion of said chip outer area, within said first insulating film, respectively and forming one wire identical to said wires on said via layer in said seal ring area; and
(1) when i is 1, depositing said first insulating film over said contact interlayer dielectric such that first and second air gaps are formed respectively in a first groove between said adjacent wires provided on the portion of said chip inner area within said contact interlayer dielectric and in a second groove between said adjacent wires provided on the portion of said chip outer area within said contact interlayer dielectric, said first and second air gaps being hermetically-closed holes and extending parallel to a thickness direction of said first insulating film, and such that all the wires provided on said contact interlayer dielectric are covered, and planarizing a top surface of said first insulating film after the deposition, whereas (2) when i is 2 or larger, depositing said first insulating film for an (i+1)-th wiring layer over said first insulating film for said i-th wiring layer such that first and second air gaps are formed respectively in a first groove between said adjacent wires provided on the portion of said chip inner area within said first insulating film and in a second groove between said adjacent wires provided on the portion of said chip outer area within said first insulating film, said first and second air gaps being hermetically-closed holes and extending parallel to the thickness direction of said first insulating film, and such that all the wires provided on said first insulating film in said i-th wiring layer are covered, and planarizing a top surface of said first insulating film after the deposition.

8. A method of manufacturing a semiconductor device comprising the steps of:
irradiating a laser dicing portion of a semiconductor wafer with a laser beam having a wavelength capable of melting only a semiconductor substrate, an air gap provided in each wiring layer in a portion corresponding to said laser dicing portion out of a first insulating film in said semiconductor wafer, said air gap extending in a thickness direction of said first insulating film and being a hermetically-closed hole, thereby to melt a part of said semiconductor substrate, said part being immediately below said laser dicing portion; and
cleaving said laser dicing portion directly above the melted part of said semiconductor substrate from said melted part of said semiconductor substrate of said semiconductor wafer, to separate a semiconductor chip from said semiconductor wafer.
